(19) United States
(12) Patent Application Publication
(10) Pub. No.: US 2025/0140656 A1
(43) Pub. Date: May 1, 2025

(54) SEMICONDUCTOR MODULE

(71) Applicant: SHINDENGEN ELECTRIC MANUFACTURING CO., LTD., Tokyo (JP)

(72) Inventors: Yuji MORINAGA, Saitama (JP); Junya YUGUCHI, Saitama (JP)

(21) Appl. No.: 18/925,022

(22) Filed: Oct. 24, 2024

(30) Foreign Application Priority Data
Oct. 31, 2023 (JP) 2023-187046

(51) Int. Cl. H01L 23/495; H01L 23/31

(52) U.S. Cl. CPC H01L 23/49555; H01L 23/49575; H01L 23/3121

(57) ABSTRACT

A semiconductor module includes: a semiconductor chip; a substrate on which the semiconductor chip is disposed; a lead terminal having a joining portion that is joined to the substrate by a conductive joining material; and a mold resin that seals at least the semiconductor chip, the substrate and a portion of the lead terminal. The lead terminal has a protruding portions that protrude toward a side of the substrate in the joining portion.

### CROSS REFERENCE TO RELATED APPLICATIONS

This application claims priority to Japanese Patent Application No. 2023-187046, filed on Oct. 31, 2023, which is expressly incorporated herein by reference in its entirety.

### TECHNICAL FIELD

The present invention relates to a semiconductor module.

### BACKGROUND ART

Conventionally, there has been known a semiconductor module where, in a mold resin, a semiconductor chip, a substrate on which the semiconductor is disposed, and a lead terminal having a joining portion that is joined to the substrate by a conductive joining material (solder) are disposed (see patent literature described below).

### PRIOR ART LITERATURE

### Patent Literature

[Patent literature 1] WO2021/117129A1

### SUMMARY OF INVENTION

### Technical Problem

However, in such a semiconductor module, because of a difference in linear expansion coefficient between the mold resin and the lead terminal, when the lead terminal expands or shrinks due to a change in temperature, the movement of the lead terminal is restricted by the mold resin.

Accordingly, there has been a concern that a large stress is applied to the conductive joining material that connects the substrate and the lead terminal to each other and hence, a crack occurs whereby a resistance value of a joining portion is increased resulting in the lowering of reliability of the semiconductor module. On the other hand, a thickness of the conductive joining material is increased to alleviate a stress applied to the conductive joining material, the securing of a supply amount of the conductive joining material arises as a problem to be solved. In a case where a width of the lead terminal is increased so as to realize the lowering of inductance and the like, a joining area is increased and hence, the above-mentioned problem becomes more serious.

The present invention has been made in view of such circumstances, and it is an object of the present invention to provide a semiconductor module that can reduce a stress applied to a conductive joining material that joins a substrate and a lead terminal to each other, and to reduce a supply amount of conductive joining material necessary for such joining.

### Solution to Problem

A semiconductor module according to the present invention includes a semiconductor chip, a substrate on which the semiconductor chip is disposed; a lead terminal having a joining portion that is joined to the substrate by a conductive joining material, and a mold resin that seals at least the semiconductor chip, the substrate and a portion of the lead terminal, wherein the lead terminal has a protruding portion that protrudes toward a side of the substrate in the joining portion.

### Advantageous Effects of the Present Invention

According to the semiconductor module of the present invention, the portion that can increase a thickness of the conductive joining material exists and hence, a stress applied to the conductive joining material that joins the substrate and the lead terminal to each other can be reduced and, at the same time, with the formation of the protruding portion, a supply amount of the conductive joining material necessary for joining can be reduced.

### BRIEF DESCRIPTION OF DRAWINGS

FIG. 1 is a plan view illustrating the internal configuration of a semiconductor module 1 according to a first embodiment.

FIG. 2 is a perspective view illustrating the structure of a lead terminal 62.

FIG. 3 is a view provided for describing the shape a joining portion 65 of the lead terminal 62.

FIG. 4 is a view illustrating a result of thermal stress simulation that uses the semiconductor module 1 according to the first embodiment.

FIG. 5. is a view provided for describing the shape of a joining portion 165 of a lead terminal 162.

FIG. 6 is a view illustrating a result of a thermal stress simulation that uses a semiconductor module 3 according to a second embodiment.

FIG. 7 is a view for describing the shape of a joining portion 365 of a lead terminal 362 that forms a conventional semiconductor module 300.

FIG. 8 is a view illustrating a result of thermal stress simulation that uses the conventional semiconductor module 300.

### DESCRIPTION OF EMBODIMENTS

Hereinafter, semiconductor modules according to the respective embodiments are described. In the respective embodiments described hereinafter, with respect to each constitutional element having substantially the same function is indicated using the same symbol in all embodiments, and the repeated description of the constitutional element is omitted. The respective embodiments described hereinafter are not intended to restrict the inventions called for in Claims. Further, it is not always the case that all of the various constitutional elements and the combinations of these constitutional elements described in the respective embodiments are indispensable as a means to solve the problems of the present invention.

### First Embodiment

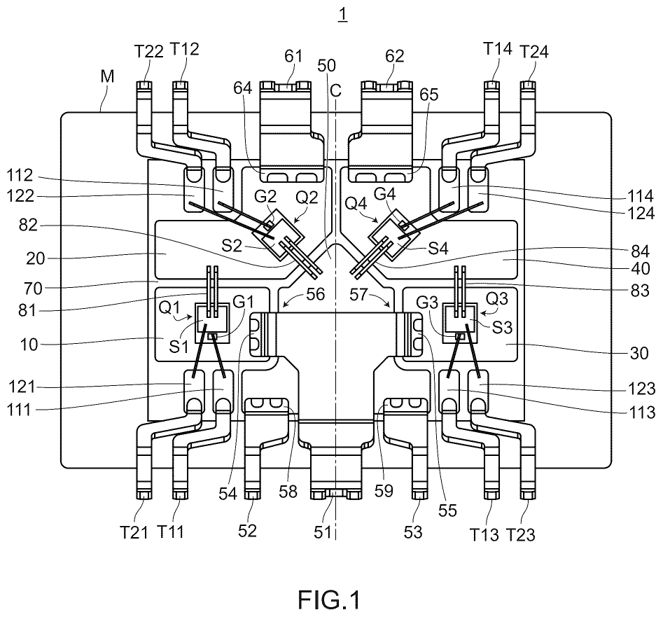

Hereinafter, the internal configuration of the semiconductor module 1 according to the first embodiment is described with reference to FIG. 1. As illustrated in FIG. 1, the semiconductor module 1 according to a first embodiment includes: a plurality of semiconductor chips that are disposed in a mold resin (only an outer edge of the mold resin being indicated by symbol M); and lead terminals 51, 52, 53. With respect to the lead terminals 51, 52, 52, an end portion (a joining portion) of an inner lead portion of each lead terminal is positioned inside the mold resin M, and an outer lead portion of each lead terminal is positioned outside the mold resin M.

Further, the semiconductor module 1 includes four semiconductor chips (first to fourth semiconductor chips Q1 to Q4) as a plurality of semiconductor chips, and also includes lead terminals 61, 62. With such a configuration, a bridge circuit is formed in the semiconductor module 1. With respect to the lead terminals 61, 62, an end portion (joining portion) of an inner lead portion of each lead terminal is positioned inside the mold resin M.

Further, the semiconductor module 1 includes, besides the above-mentioned constitutional elements, first to fifth wiring patterns 10 to 50, a substrate 70, first to fourth connecting members 81 to 84, first to fourth control-use connecting members (symbols of these members not being indicated in the drawings), first to fourth detection-use connecting members (symbols of these members not being indicated in the drawings), first to fourth control-use wiring patterns 111 to 114, first to fourth detection-use wiring patterns 121 to 124, first to fourth control-use terminals T11 to T14, and first to fourth detection use terminals T21 to T24. The first to fifth wiring patterns 10 to 50 form portions of the substrate 70. The semiconductor module 1 may also include other constitutional elements besides the above constitutional elements. In the semiconductor module 1, the bridge circuit is formed in such a manner that the first semiconductor chip Q1 and the third semiconductor chip Q3 are disposed on a high side and the second semiconductor chip Q2 and the fourth semiconductor chip Q4 are disposed on a low side.

In the semiconductor module 1, the first semiconductor chip Q1 and the third semiconductor chip Q3 are arranged in line symmetry with respect to a center line C, and the second semiconductor chip Q2 and the fourth semiconductor chip Q4 are arranged in line symmetry with respect to the center line C. Such line symmetrical arrangement relationship with respect to the center line C is also adopted between the first wiring pattern 10 and the third wiring pattern 30, between the second wiring pattern 20 and the fourth wiring pattern 40, between the lead terminal 52 and the lead terminal 53, and between the lead terminal 61 and the lead terminal 62. Further, such line symmetrical arrangement relationship with respect to the center line C is adopted between the fifth wiring pattern 50 and the lead terminal 51.

The lead terminal 51 is constituted of lead terminals 56, 57 that function as input power source terminals. That is, the lead terminals 52, 53 function as input power source terminals. The lead terminals 61, 62 function as output power source terminals.

### [Structure of Lead Terminal]

Hereinafter, the structures of the lead terminals 52, 53, 56, 57, 61, 62 are described. However, the structures of the joining portions 54, 55, 58, 59, 64, 65 are substantially the same and hence, in this embodiment, the description is made by taking the lead terminal 62 as an example, and the structures of other lead terminals 52, 53, 56, 57, 61 are omitted. Further, although the joining portions of the respective lead terminals 52, 53, 56, 57, 61, 62 are jointed to the wiring patterns on the substrate 70, in the following description, the description is made by assuming that the wiring patterns also form portions of the substrate 70.

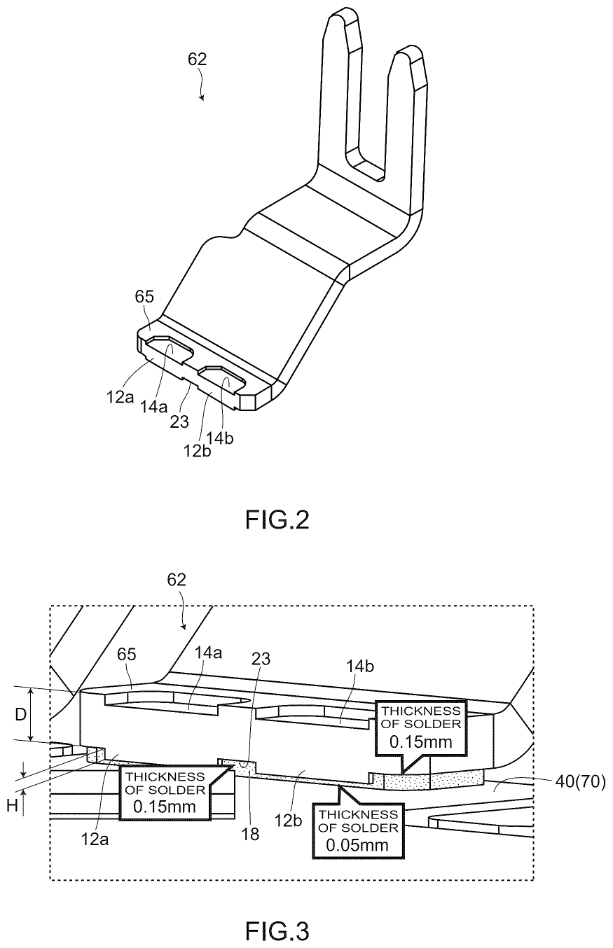

As illustrated in FIG. 3, the lead terminal 62 includes the joining portion 65 at a distal end thereof, and the joining portion 65 is joined to the wiring pattern 40 via a conductive joining material 18. In this embodiment, the conductive joining material 18 is solder (solder in the broad meaning of the term thus including lead-free solder and the like). The joining portion 65 includes protruding portions 12a, 12b that protrude toward a surface (upper surface) of the substrate 70 on which the fourth wiring pattern 40 is formed from an outer peripheral end surface 23 of the joining portion 65. The protruding portions 12a, 12b are disposed so as to abut against an edge of the joining portion 65. The example illustrated in FIG. 2 is an example where two protruding portions 12a, 12b are formed in a space-apart manner with a predetermined distance therebetween. However, only one protruding portion 22 may be formed as illustrated in FIG. 5, or three or more protruding portions may be formed at a predetermined interval (not illustrated in the drawing). The protruding portions 12a, 12b may be formed by press forming by applying pressing to an upper surface of the joining portion 65. However, the protruding portion forming method is not limited to such a method. Recessed portions 14a, 14b are respectively portions (byproducts) that are formed at the time of forming the protruding portions 12a, 12b by pressing. It is preferable that a height H of the protruding portions 12a, 12b be not less than 0.1 mm and be not more than half of a plate thickness D of the joining portion 65.

The conductive joining material 18 in a paste form is applied to the substrate 70 by coating (for example, printing or the like), the lead terminal 62 is mounted on the substrate 70 and, then, heat is applied to the conductive joining material 18. As a result, the conductive joining material 18 is melted so that the joining portion 65 is joined to the substrate 70. At this point of time, the conductive joining material 18 spreads in a wet form into a space formed between the protruding portion 12a and the protruding portion 12b that are disposed adjacently to each other.

### [Thermal Stress Simulation]

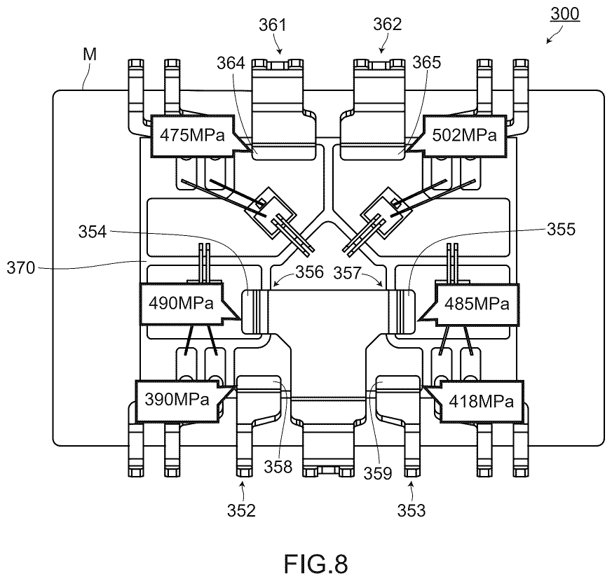

On a condition that the thickness of the conductive joining material where the protruding portions 12a, 12b do not exist on a lower end surface of the joining portion 65 is set to 0.15 mm (see FIG. 3), thermal stresses that were applied to the conductive joining material 18 that joined the lead terminal 56, the lead terminal 57, the lead terminal 52, the lead terminal 53, the lead terminal 61, and the lead terminal 62 to the substrate 70 respectively to each other were measured. On the other hand, in a comparison example (the configuration of the prior art), thermal stresses that were applied to a conductive joining material 348 that joined lead terminals 352, 353, 356, 357, 361, 362 to a substrate 370 that constitute a semiconductor module 300 illustrated in FIG. 8 were measured. No protruding portions were formed on the joining portions of these lead terminals (for example, the joining portion 365 illustrated in FIG. 7). A temperature change condition for generating the thermal stress was set from −55° C. to 175° C. (temperature difference: 230° C.).

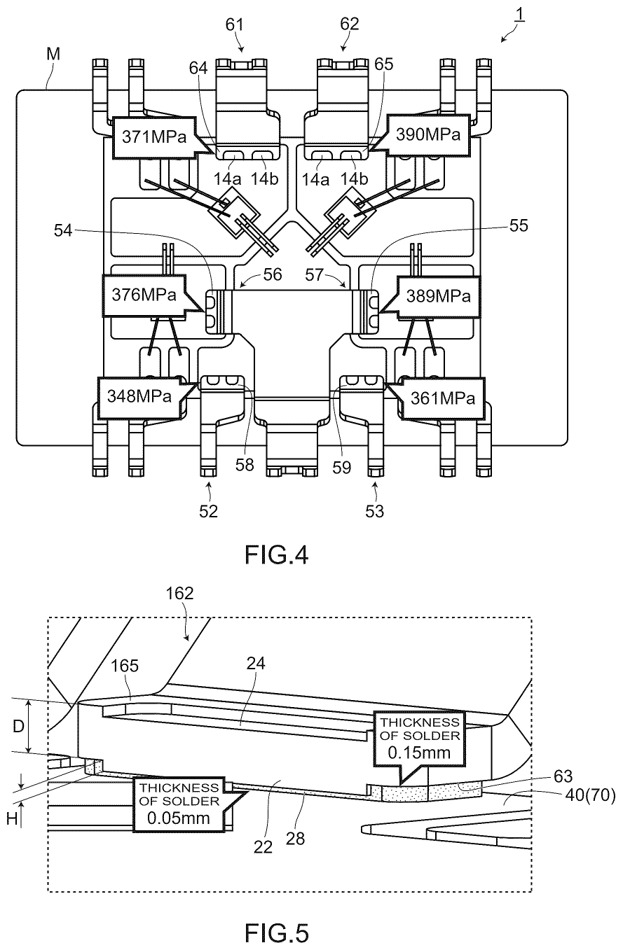

The simulation result in the thermal stress simulation in the first embodiment is illustrated in FIG. 4. As illustrated in FIG. 4, the thermal stress of 376 MPa was detected in the lead terminal 56, the thermal stress of 389 MPa was detected in the lead terminal 57, the thermal stress of 348 MPa was detected in the lead terminal 52, the thermal stress of 361 MPa was detected in the lead terminal 53, the thermal stress of 371 MPa was detected in the lead terminal 61, and the thermal stress of 390 MPa was detected in the lead terminal 62. In the simulation result (comparison result) in the thermal stress simulation in the comparison example, as illustrated in FIG. 8, the thermal stress of 490 MPa was detected in the lead terminal 356, the thermal stress of 485 MPa was detected in the lead terminal 357, the thermal stress of 390 MPa was detected in the lead terminal 352, the thermal stress of 418 MPa was detected in the lead terminal 353, the thermal stress of 475 MPa was detected in the lead terminal 361, and the thermal stress of 502 MPa was detected in the lead terminal 362. As a result, it is understood that, according to the configuration of the present embodiment, the thermal stresses that were applied to the conductive joining material 18 that joined the respective lead terminals 52, 53, 56, 57, 61, 62 to the substrate 70 respectively were reduced compared to the thermal stresses (see FIG. 8) applied to the conductive joining material 348 that joined the lead terminals 352, 353, 356, 357, 361, and 362 disposed at the same position to the substrate in the conventional configuration (the configuration having neither the protruding portion 12a nor the protruding portion 12b).

With the above-mentioned configuration, even when the lead terminal 62 expands or shrinks due to a change in temperature caused by the difference in linear expansion coefficient between the mold resin M and the lead terminal 62, a thickness (solder thickness) of the conductive joining material 18 is increased by an amount of a height H of the protruding portions 12a, 12b and hence, the occurrence of a crack can be suppressed. Accordingly, it is possible to suppress a stress applied to the conductive joining material 18 that joins the substrate 70 and the lead terminal 62 to each other. Further, compared to a case where only a thickness of the conductive joining material 18 is increased for alleviating a stress applied to the conductive joining material 18, a supply amount of the conductive joining material 18 can be also easily reduced because of the existence of the protruding portions 12a, 12b. As a result, according to the above-mentioned configuration, a stress applied to the conductive joining material 18 that joins the substrate 70 and the lead terminal 62 to each other can be reduced and, at the same time, a supply amount of the conductive joining material 18 necessary for joining can be reduced.

Also in a case of increasing a width of the lead terminal for the purpose of lowering inductance, a large amount of conductive joining material (solder) becomes necessary. However, an amount of conductive joining material that is applicable to the substrate by coating in a stable manner or with certainty is limited and hence, it is desirable to reduce an amount of conductive joining material to a reasonable amount. According to the above-mentioned configuration, a supply amount of conductive joining material can be easily adjusted by properly adjusting a height and an area of the protruding portion and hence, it is possible to acquire an advantageous effect that the degree of freedom in the adjustment of a supply amount of conductive joining material can be increased. Further, a joining area of the conductive joining material can be increased with the formation of the protruding portions and hence, a joining strength can be easily increased.

### Second Embodiment

A semiconductor module 3 according to a second embodiment basically differs from the semiconductor module 1 according to the first embodiment 1 with respect to a point that only one protruding portion 22 is formed in the semiconductor module 3 according to the second embodiment. Hereinafter, only the point that makes the semiconductor module 3 according to the second embodiment differ from the semiconductor module 1 according to the first embodiment is described, and the description of parts substantially equal to the corresponding parts in the first embodiment is omitted. Hereinafter, in the same manner as the first embodiment described above, the description is made by taking a lead terminal 162 as an example, and the description of the structures of other lead terminals 152, 153, 156, 157, 161 is omitted.

As illustrated in FIG. 5, the lead terminal 162 includes a joining portion 165 at a distal end thereof, and the joining portion 165 is joined to the wiring pattern 40 via a conductive joining material 28. The joining portion 165 has a protruding portion 22 that protrudes toward a surface (upper surface) of a substrate 70 on which the fourth wiring pattern 40 is formed from an outer peripheral end surface (not indicated by symbol in the drawing) of the joining portion. The protruding portion 22 may be formed by press forming by applying pressing to an upper surface of the joining portion 165. However, the protruding portion 22 forming method is not limited to such a method. A recessed portion 24 is a portion (a byproduct) that is formed at the time of forming the protruding portion 22 by pressing. It is preferable that a height H of the protruding portion 22 be not less than 0.1 mm and be not more than half of a plate thickness D of the joining portion 65.

The conductive joining material 28 in a paste form is applied to the substrate 70 by coating (for example, printing or the like) in advance, the lead terminal 162 is mounted on the substrate 70 and, then, heat is applied to the conductive joining material 28. As a result, the conductive joining material 28 is melted so that the joining portion 165 is joined to the substrate 70. At this point of the time, the conductive joining material 28 spreads in a wet form into a space formed below an outer peripheral end surface 63 of the joining portion 165 where the protruding portion 22 does not exist.

### [Thermal Stress Simulation]

Hereinafter, on a condition that a thickness (solder thickness) of the conductive joining material 28 that exists between a lower end surface of the protruding portion 22 to the substrate 70 is set to 0.05 mm (see FIG. 5) and the thickness of the conductive joining material 28 at portions of a lower end surface of the joining portion 165 where the protruding portion 22 does not exist is set to 0.15 mm (see FIG. 5), thermal stresses that were applied to the conductive joining material 28 that joined the lead terminal 156, the lead terminal 157, the lead terminal 152, the lead terminal 153, the lead terminal 161, and the lead terminal 162 to the substrate 70 respectively were measured. On the other hand, in a comparison example (the configuration of the prior art), thermal stresses applied to a conductive joining material 348 that joins the lead terminals 352, 353, 356, 357, 361, and 362 that constitute the semiconductor module 300 illustrated in FIG. 8 to the substrate 370 were measured. No protruding portions were formed on the joining portions of these lead terminals (for example, the joining portion 365 in FIG. 7). A temperature change condition for generating the thermal stress was set substantially in the same manner as the first embodiment.

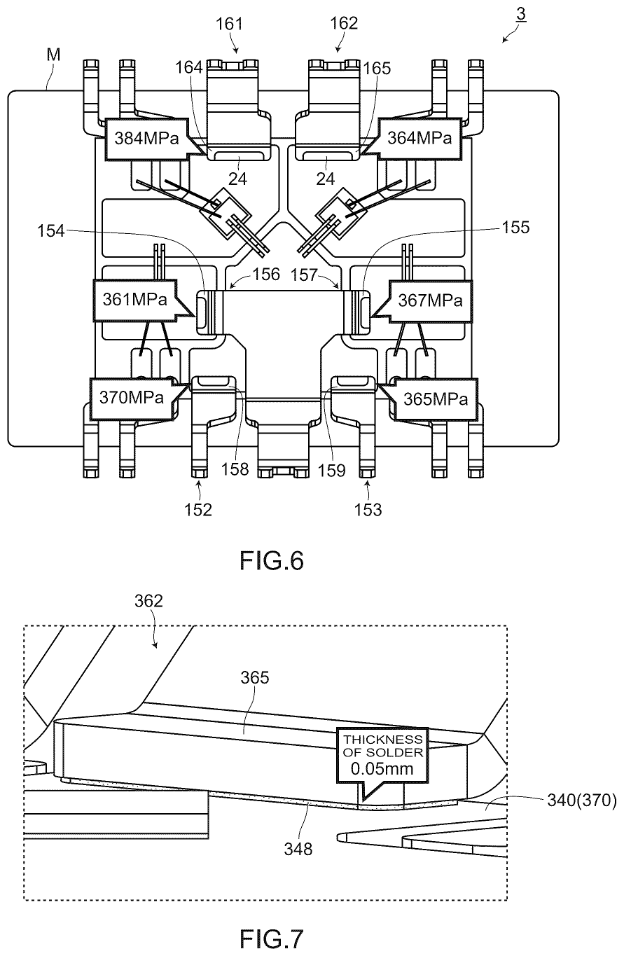

The measurement result in the thermal stress simulation in the second embodiment is illustrated in FIG. 6. As illustrated in FIG. 6, the thermal stress of 361 MPa was detected in the lead terminal 156, the thermal stress of 367 MPa was detected in the lead terminal 157, the thermal stress of 370 MPa was detected in the lead terminal 152, the thermal stress of 365 MPa was detected in the lead terminal 153, the thermal stress 384 MPa was detected in the lead terminal 161, and the thermal stress 364 MPa was detected in the lead terminal 162. As a result, it is understood that, according to the configuration of the present embodiment, the thermal stresses that were applied to the conductive joining material 28 that joined the respective lead terminals 152, 153, 156, 157, 161, and 162 to the substrate 70 respectively were reduced compared to the thermal stresses (see FIG. 8) applied to the conductive joining material 348 that joined the lead terminals 352, 353, 356, 357, 361, and 362 disposed at the same position in the conventional configuration (comparison example) to the substrate 370.

### [Recapitulation of Advantageous Effects]

The semiconductor module according to the above-mentioned embodiment includes the semiconductor chip, the substrate on which the semiconductor chip is disposed, the lead terminal having a joining portion that is joined to the substrate by the conductive joining material, and the mold resin that seals at least the semiconductor chip, the substrate and a portion of the lead terminal, wherein the lead terminal has a protruding portion that protrudes toward a side of the substrate in the joining portion. Accordingly, with the above-mentioned configuration, the portion where the thickness of the conductive joining material can be increased exists and hence, a stress applied to the conductive joining material that connects the substrate and the lead terminal to each other can be reduced, and at the same time, with the formation of the protruding portion, a supply amount of the conductive joining material necessary for joining can be reduced.

In the semiconductor modules according to the above-mentioned embodiments, the lead terminal may include a plurality of protruding portions as the protruding portion. Accordingly, by suitably adjusting heights and widths of the plurality of protruding portions, a supply amount of the conductive joining material can be adjusted more easily and hence, it is possible to acquire an advantageous effect that the degree of freedom in adjusting the supply amount of the conductive joining material can be increased. By forming the plurality of protruding portions, a joining area between the joining portion and the conductive joining material can be increased and hence, a joining strength is increased.

In the semiconductor module according to the above-mentioned embodiment, it is preferable that the protruding height of the protruding portion that protrudes toward the side of the substrate is not less than 0.1 mm, and not more than half of the plate-thickness of the joining portion. The reason that the height of the protruding portion is decided as described above is as follows. In a case where the height of the protruding portion is high, a large amount of conductive joining material becomes necessary, and in a case where the height of the protruding portion becomes excessively high, an entire gap formed between the protruding portion and the protruding portion makes it difficult for the conductive joining material to spread by wetting. In a case where the height of the protruding portion is excessively low, it is difficult for the conductive joining material to secure a thickness thus giving rise to a possibility that the alleviation of a stress becomes difficult. Accordingly, by controlling the height of the protruding portion such that the height of the protruding portion is not less than 0.1 mm and not more than half of the plate-thickness of the joining portion, it is possible to acquire an advantageous effect that the conductive joining material easily spreads by wetting.

In the semiconductor module according to the above-mentioned embodiment, it is desirable that the protruding portion be disposed so as to abut against the edge of the joining portion. In a case where the protruding portion does not abut against the edge, a size of the protruding portion becomes small and hence, an amount of conductive joining material necessary for joining is increased.

However, by arranging the protruding portion such that the protruding portion abuts against the edge of the joining portion, a size of the protruding portion is increased and hence, it is possible to expect an effect of reducing an amount of conductive joining material.

In the semiconductor modules according the above-mentioned embodiments, it is desirable that the joining portion be the end portion of the lead terminal. By forming the joining portion on the end portion of the lead terminal, it is possible to arrange the protruding portion such that the protruding portion abuts against the edge and hence, the larger protrusion can be formed whereby a supply amount of the conductive joining material can be reduced.

The present invention is not limited to the above-mentioned embodiments, and various modifications can be carried out without departing from the gist of the present invention. For example, a case is considered where the joining portion is joined to the semiconductor chip besides the case where the joining portion is joined to the wiring pattern on the substrate.

### LIST OF SYMBOLS AND SIGNS

1, 3, 300: semiconductor module
12a, 12b, 22: protruding portion
14a, 14b, 24: recessed portion
18, 28: conductive joining material (solder)
51, 52, 53, 56, 57, 61, 62, 152, 153, 156, 157, 161, 162: lead terminal
54, 55, 58, 59, 64, 65, 154, 155, 158, 159, 164, 165: joining portion
70: substrate
Q1, Q2, Q3, Q4: semiconductor chip
M: mold resin

1. A semiconductor module comprising:
a semiconductor chip; a substrate on which the semiconductor chip is disposed; a lead terminal having a joining portion that is joined to the substrate by a conductive joining material; and a mold resin that seals at least the semiconductor chip, the substrate and a portion of the lead terminal, wherein
the lead terminal has a protruding portion that protrudes toward a side of the substrate in the joining portion.

2. The semiconductor module according to claim 1, wherein
the lead terminal includes a plurality of protruding portions as the protruding portion.

3. The semiconductor module according to claim 1, wherein
a protruding height of the protruding portion that protrudes toward the side of the substrate is not less than 0.1 mm, and is not more than half of a plate-thickness of the joining portion.

4. The semiconductor module according to claim 1, wherein
the protruding portion is disposed such that the protruding portion abuts against an edge of the joining portion.

5. The semiconductor module according to claim 1, wherein
the joining portion is an end portion of the lead terminal.
